(19) United States
(12) Patent Application Publication
(10) Pub. No.: US 2007/0275577 A1
(43) Pub. Date: Nov. 29, 2007

(54) Circuit board

(75) Inventor: Kenta Masumori, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kanagawa (JP)

(21) Appl. No.: 11/802,362

(22) Filed: May 22, 2007

(30) Foreign Application Priority Data
May 23, 2006 (JP) 2006-142731

(51) Int. Cl. H05K 1/00

(52) U.S. Cl. 439/76.1

(57) ABSTRACT

An adapter card for extending functions of a computer includes a first male connector mounted to a female connector of an expansion slot provided to the computer in a way the first male connector can be inserted/removed into/from the female connector and a second male connector that corresponds to a bus architecture same as the first male connector in a way the second male connector can be inserted/removed into/from the female connector.

### BACKGROUND OF THE INVENTION

1. Field of the Invention

The present invention relates to a circuit board.

2. Description of Related Art

Conventionally, as a system bus for computers including personal computer, PCI (Peripheral Component Interconnect) buses are mainly employed. A female connector for PCI is provided in a motherboard of a general computer. A user inserts a male connector of an adapter card into the female connector depending on the usage. To cater for a wide range of usages, a technique is developed in which a plurality of LSIs (Large Scale Integration) having terminals for PCI are mounted to one adapter card to accomplish several functions with one adapter card. It is desired to implement several functions to one adapter card and also to reduce the cost of the adapter card.

For example in Japanese Unexamined Patent Application Publication No. 2000-172632, an adapter card including a LSI with a bus switching function is disclosed. The LSI being mounted switches several types of interfaces and the adapter card can be connected to the same PCI bus. Therefore, a LSI having a bus bridge function must be additionally mounted to the adapter card and thus it is difficult to reduce the cost.

Further in Japanese Unexamined Patent Application Publication No. 11-175193, an adapter card is disclosed that includes connectors of female and male mounted to top and bottom of the adapter card. In the adapter card, one of the two connectors is a receptacle, so it cannot be inserted and removed into/from a female connector on a motherboard.

In Japanese Unexamined Patent Application Publication No. 3-27464, an adapter card is disclosed that has independent two edge connectors for bus architecture to opposite sides of one adapter card. In this adapter card, a plurality of LSIs are mounted to one adapter card.

In this adapter card, each of the two edge connectors corresponds to different bus architectures. Thus the two edge connectors cannot correspond to one kind of bus architecture on a motherboard. Further, as two kinds of edge connectors are used to opposite sides, two brackets must be prepared for each of connectors. Moreover, as a connector board assembly also must be prepared, it is difficult to reduce the cost.

We have now been discovered that in the conventional adapter card, functions cannot be easily changed.

### SUMMARY

According to an aspect of the present invention, there is provided a circuit board that includes a main board and a plurality of connectors selectively inserted and removed into/from a same slot. This enables to easily select a function to use.

The present invention provides a circuit board that is capable of changing functions of a system having the circuit board without losing electric characteristic.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a plan pattern view showing an example of the external structure of the adapter card according to the present invention;

FIG. 2A is a top view showing an example of the structure of a bracket according to the present invention;

FIG. 2B is a front view showing an example of the structure of the bracket according to the present invention;

FIG. 2C is a side view showing an example of the structure of the bracket according to the present invention;

FIG. 3A is a plan pattern view showing an example of a mode of use of the adapter card according to the present invention;

FIG. 3B is a plan pattern view showing an example of a mode of use of the adapter card according to the present invention;

FIG. 4 is a plan pattern view showing an example the external structure of the adapter card according to the present invention;

FIG. 5 is a plan pattern view showing an example of the wiring arrangement of the adapter card according to the present invention;

FIG. 6 is a plan pattern view showing an example of a mode of use of the adapter card according to the present invention;

FIG. 7 is a plan pattern view showing an example of the external structure of the adapter card according to the present invention;

FIG. 8 is a plan pattern view showing an example of the wiring arrangement of the adapter card according to the present invention; and

FIG. 9 is a plan pattern view showing an example of a mode of use of the adapter card according to the present invention.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

A circuit board of the present invention includes two kinds of male connectors according to the same bus architecture and two kinds of the male connectors are inserted into one kind of female connector that corresponds to each of them. The circuit board according to the present invention further includes an adopter card having two LSI mounted therein, where wiring groups of the two LSIs are independent to each other.

In detail, a connector of the circuit board according to the present invention preferably has a shape compliant to the PCI standard and formed in the size that fits the standard for PCI short card. Further, the shape of the connector may be compliant to the standard such as ISA and PCI-Express.

A preferred embodiment of the present invention is described hereinafter in detail with reference to the drawings. An adopter card inserted and removed into/from a computer slot is described as a preferable example of the circuit board according to the present invention, however it may be other form as long as the abovementioned feature is included.

### First Embodiment

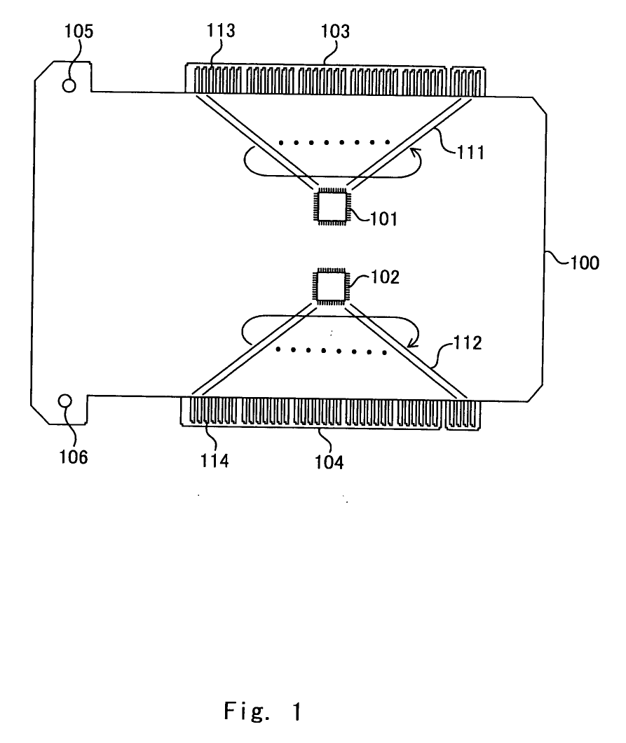

An adopter card according to the present invention is described hereinafter in detail with reference to FIG. 1. FIG. 1 is a plan pattern view showing a structure example of the adopter card. As shown in FIG. 1, an adopter card 100 includes a first LSI 101, second LSI 102, first male connector 103, second male connector 104, screw holes 105 and 106.

The LSIs 101 and 102 are examples of a circuit device performing predetermined functions that are placed over the principle surface of the rectangle adopter card 100 and fixed near the center of the principle surface. The LSIs 101 and 102 are connected to wiring groups 111 and 112 respectively by each terminal for PCI (not shown) and also connected to metal terminals 113 and 114 of the male connectors 103 and 104 via the wiring groups 111 and 112.

The male connectors 103 and 104 are placed to long sides of the rectangle adaptor card 100, being symmetric each other with respect to a center line (symmetry axis) running through the center of short sides that are parallel to the long sides. That is, on the adopter card 100, a male connector is placed opposed to another male connector that is compliant to the general PCI standard. Further, the position to place the LSIs 101 and 102 and the region to place the wiring groups 111 and 112 are not limited especially but they may be placed symmetric with respect to a line as with the male connectors 103 and 104.

The male connectors 103 and 104 correspond to the same bus architecture. Therefore, the metal terminals 113 and 114 have same structure, shape and especially arrangement. Although the metal terminals 113 and 114 have the same structure and shape, the male connectors 103 and 104 may have different shapes and sizes. In such case, a larger male connector has metal terminals in the same arrangement as the arrangement of the metal terminals for a smaller male connector. Specifically, the metal terminals in the same arrangement are placed to the same position of the larger and smaller male connectors. In other words, the metal terminals for the male connectors 103 and 104 are placed to the position corresponding to each terminal in a way the metal terminals can be connected with the terminals in the slot. The shape and size of the male connectors 103 and 104 may be different.

The screw holes 105 and 106 are an example of a fixing means to mount the adopter card 100 to a bracket, which is explained later in detail. Instead of the screw holes 105 and 106, various fixing means such as an insertion slot may be used. The distances from the center point of the screw holes 105 and 106 to the top and bottom edges of the adapter card 100 are same. The screw holes 105 and 106 are provided to corner portions where the long and short sides of the rectangle adaptor card 100 intersect. Further, the screw holes 105 and 106 are placed symmetric to the symmetric axis of the male connectors 103 and 104 placed symmetric with respect to a line.

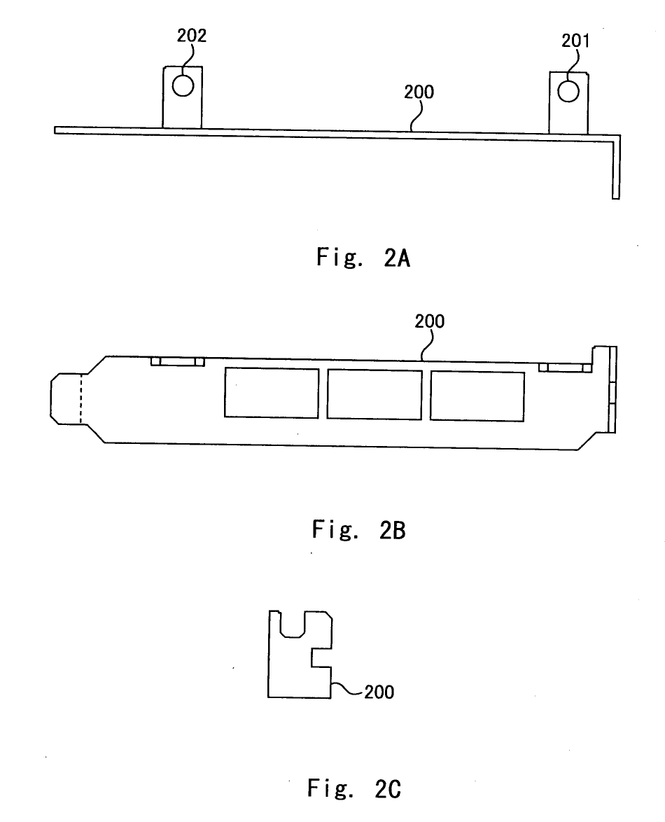

The configuration of the bracket according to the present invention is described hereinafter with reference to FIGS. 2A to 2C. FIGS. 2A to 2C are schematic diagrams showing a configuration example of the bracket. FIG. 2A is a top view, FIG. 2B is a front view when viewed from the bottom of FIG. 2A and FIG. 2C is a side view when viewed from right of FIG. 2A.

As shown in FIGS. 2A to 2C, the bracket 200 is a bracket for fixing the adapter card 100 to a computer when mounting the adapter card 100 to a PCI female connector (expansion slot) of the computer.

Specifically, the bracket 200 includes screw holes 201 and 202. The screw holes 201 and 202 are fitting holes for mounting the adapter card 100. The screw holes 201 and 202 are positioned so that the distance between the center points is equal to the distance between the center points of the screw holes 105 and 106.

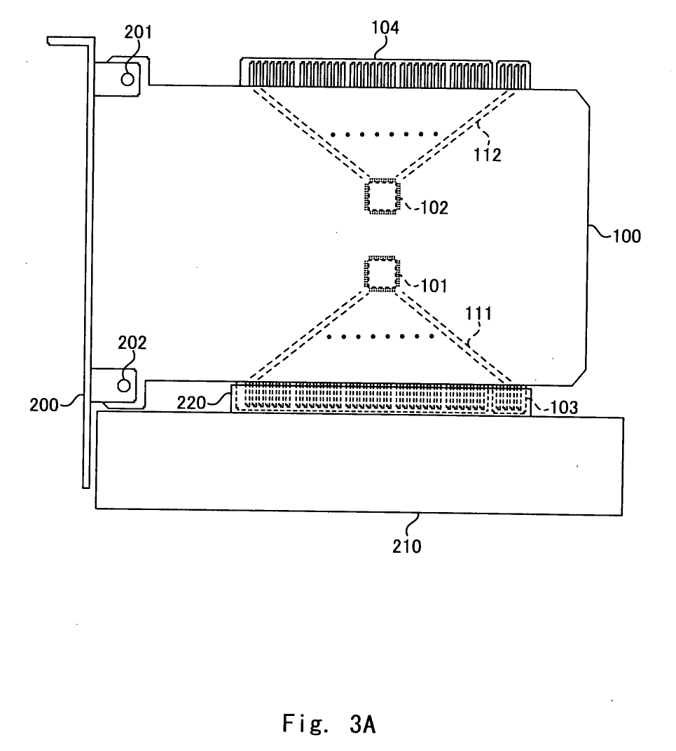

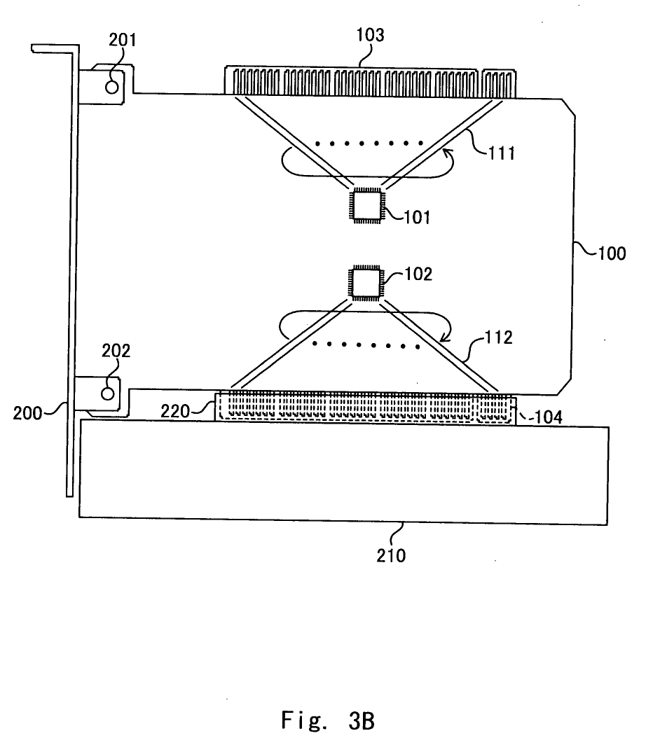

Next, a mode of use of the adapter card 100 according to the present invention is described hereinafter in detail with reference to FIG. 3. FIG. 3 is a plan pattern view for explaining the mode of use.

A user is able to use the functions of the LSIs 101 and 102 by changing the direction to insert the adapter card 100 into a computer 210. To be specific, as shown in FIG. 3A when the user uses the function of the first LSI 101, the screw hole 105 of the adapter 100 is overlapped with the screw hole 202 of the bracket 200, and the screw hole 106 of the adapter card 100 is overlapped with the screw hole 201 of the bracket 200. The overlapped screw holes 105 and 202, and screw holes 106 and 201 are screwed. In this way, the bracket 200 is fixed to the adapter card 100.

The first male connector 103 is inserted into a female connector 220 of the computer 210 with the adapter card 100 mounted to the bracket 200. After that, although not shown, the computer 210 is fixed to the bracket 200 by a fixing means such as a screw. This enables to exchange signals between the computer 210 and the first LSI 101 so that the user is able to use the function of the first LSI 101.

When the user uses the function of the second LSI 102 instead of the function of the first LSI 101, the adapter card 100 is turned upside down from the state for using the function of the first LSI 101 as shown in FIG. 3B. Specifically, the fixing means such as a screw that is used to fix the computer 210 with bracket 200 is removed temporarily to take out the first male connector 103 from the female connector 220. The adapter card 100 can be removed from the computer 210 in this way.

Then the screw used to fix the adapter card 100 with the bracket 200 is removed and the adapter card 100 is turned upside down. In other words, the adapter card 100 that is removed from the bracket 200 is rotated 180 degrees around the symmetric axis of the male connectors 103 and 104 that are placed symmetric with respect to a line. Then the opposite sides of the adapter card 100 are reversed. The screw hole 105 of the adapter card 100 is overlapped with the screw hole 201 of the bracket 200, and the screw hole 106 of the adapter card 100 is overlapped with the screw hole 202 of the bracket 200, then the holes are screwed.

The second male connector 104 is inserted into the female connector 220 of the computer 210 with the adapter card 100 mounted to the bracket 200. After that, although not shown, the computer 210 and bracket 200 are fixed by a fixing means such as a screw. This enables to exchange signals between the computer 210 and the second LSI 102, thus the function of the second LSI 102 can be used.

As described in the foregoing, to use each function of the LSI 101 or LSI 102, the adapter card 100 is turned over to either side and fixed to the bracket 200 before inserting the male connector 103 or 104 into the female connector 220 correspondingly. In other words, the placement of the adapter card 100 for the female connector 220 is selected as appropriate as either one of the male connector 103 or 104 is inserted into. Specifically, the placement of the adapter card 100 is selected so that either of the male connectors 103 or 104 faces the female connector 220 of the computer 210.

As described in the foregoing, in the present invention, two opposing male connectors 103 and 104 are provided to one adaptor card 100. Therefore, by turning the adapter card 100 upside down, the male connector 103 or 104 to use can be easily selected. As the LSIs 101 and 102 are mounted correspondingly to the male connectors 103 and 104, by changing the male connector 103 or 104 to use, the functions of the LSIs 101 and 102 can be switched. Especially in the adapter card 100 according to the present invention, as the LSIs 101 and 102 are directly connected to the male connectors 103 and 104 without intervening a switching means such as a switch and selector, by changing the direction to insert the adapter card 100, the male connector 103 or 104 to use can be changed. Further, by turning the adapter card 100 upside down to fix to the same bracket 200, it is not necessary to prepare two kinds of brackets corresponding to each of the male connectors 103 and 104. Therefore, the cost of the adapter card 100 can be suppressed from increasing so as to achieve the low-cost adapter card 100 having multiple functions.

Generally to mount a plurality of LSIs on one adapter card, a switch is provided to a wiring group between the plurality of LSIs and PCI male connector and a signal line group is diverted that can be used in common to several LSIs such as address and data lines. In such case, there are problems such as a switch delay by a switch circuit and deterioration of signal quality by the increase of parasitic capacity.

In the present invention, each of the LSIs 101 and 102 is connected to the male connectors 103 and 104 via the wiring groups 111 and 112, respectively. Therefore, the same configuration can be achieved as only one LSI is mounted to the adapter card 100. Thus it is possible to largely improve the problem of switch delay and that parasitic capacity increases to deteriorate signal quality. Further, as the LSI 101 is directly connected with the male connector 103 and the LSI 102 is directly connected with the male connector 104, it is not required to include a device having a bus bridge function for switching them. Thus the low-cost adopter card 100 can be accomplished.

### Second Embodiment

In a second embodiment, two LSIs are mounted as with the first embodiment. However in an adopter card of the second embodiment, the LSIs 101 and 102 each functions as a USB controller and IEEE 1394 controller.

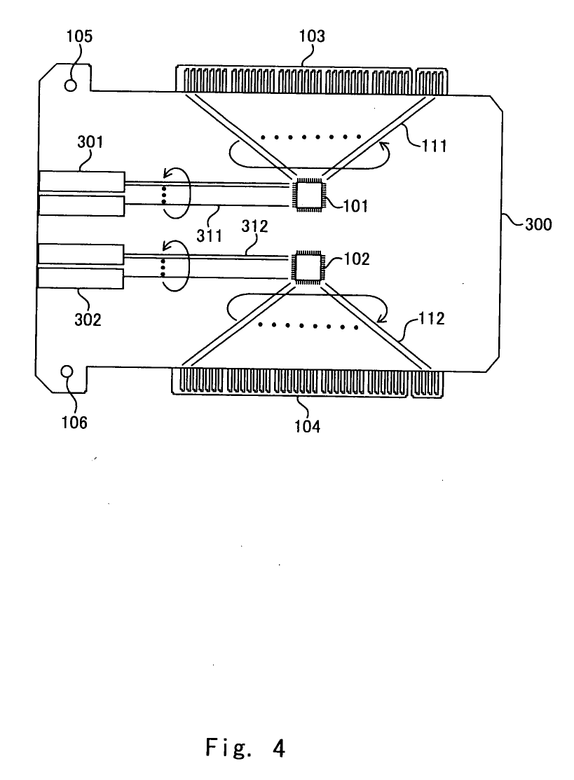

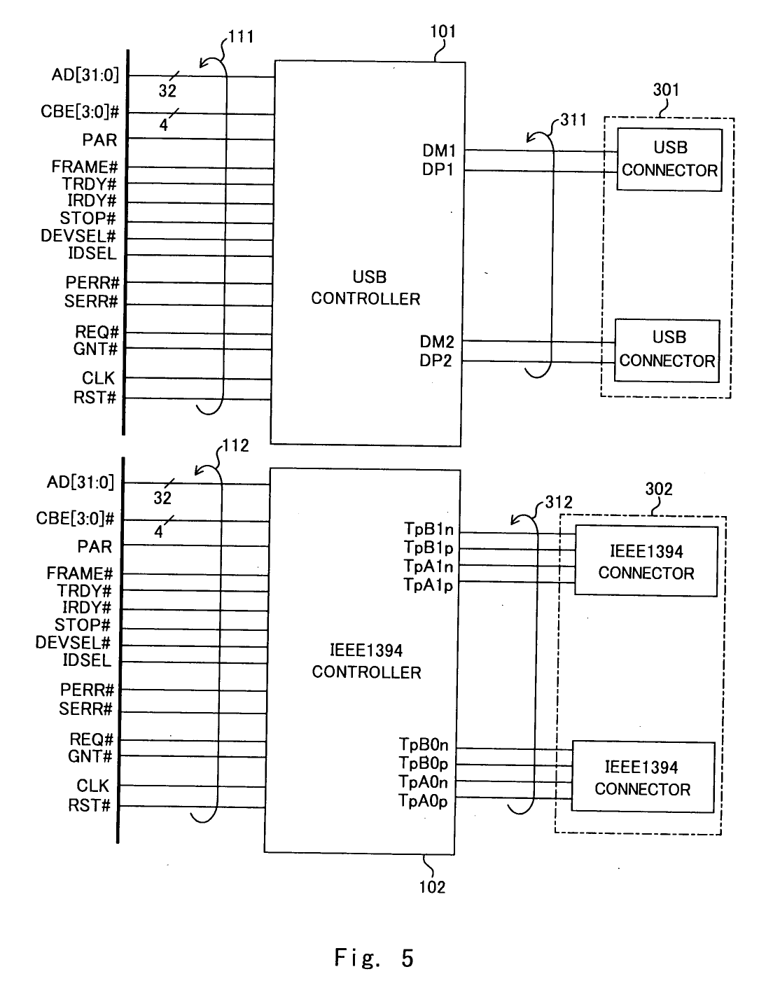

The configuration of the adopter card according to the second embodiment is described hereinafter in detail with reference to FIGS. 4 and 5. FIG. 4 is a plan pattern view showing a structure example of the adopter card according to the second embodiment. Hereinafter, like parts in the adapter card 100 of the first embodiment are marked throughout the specification with the same reference numerals with description omitted.

As shown in FIG. 4, the adapter card 300 includes a first device side connector 301 and a second device side connector 302 in addition to the configuration of the first embodiment. The device side connector 301 functions as a USB connector corresponding to the LSI 101. On the other hand, the device side connector 302 functions as an IEEE 1394 connector corresponding to the LSI 102.

The device side connectors 301 and 302 are placed on the principle surface of the rectangle adapter card 200 and are fixed to the surface where the LSIs 101 and 102 are placed. Specifically, the device side connectors 301 and 302 are placed near the short sides where the screw holes 105 and 106 are placed. The device side connector 301 is connected to the wiring group 311 and to the LSI 101 by the wiring group 311. The device side connector 302 is connected to the wiring group 312 and to the LSI 102 by the wiring group 312. The wiring group 311 may connect the device side connector 301 with the LSI 101. Further, the wiring group 312 may connect the device side connector 302 with the LSI 102.

In FIG. 4, the wiring groups 311 and 312 extends along the long side of the adapter card 300 as the LSIs 101 and 102 are placed distant from the device side connectors 301 and 302.

A wiring structure of the adopter card 300 according to the second embodiment is described hereinafter in detail with reference to FIG. 5.

FIG. 5 is a block diagram showing an example of a connection wiring of the adopter card 300 according to the present invention. As shown in FIG. 5, the wiring groups 111 and 311 of the first LSI 101 and the wiring groups 112 and 312 of the second LSI 102 are completely independent.

Specifically, the first LSI 101 that functions as a USB controller inputs/outputs various signals “AD[31:0]”, “CBE[3:0]”, . . . with the computer 210 via the wiring group 111. Further, the first LSI 101 inputs/outputs various signals “DM1”, “DP1”, . . . with the USB connector 301 via the wiring group 311. In this way, the computer 210 and a peripheral device having a USB interface inputs/outputs various signals.

The second LSI 102 that functions as a IEEE 1394 controller inputs/outputs various signals “AD[31:0]”, “CBE[3:0]”, . . . with the computer 210 via the wiring group 112. Further, the second LSI 102 inputs/outputs various signals “TpB1n”, “TpB1p”, . . . with the IEEE 1394 connector 302 via the wiring group 312. In this way, the computer 210 and a peripheral device having an IEEE 1394 interface inputs/outputs various signals.

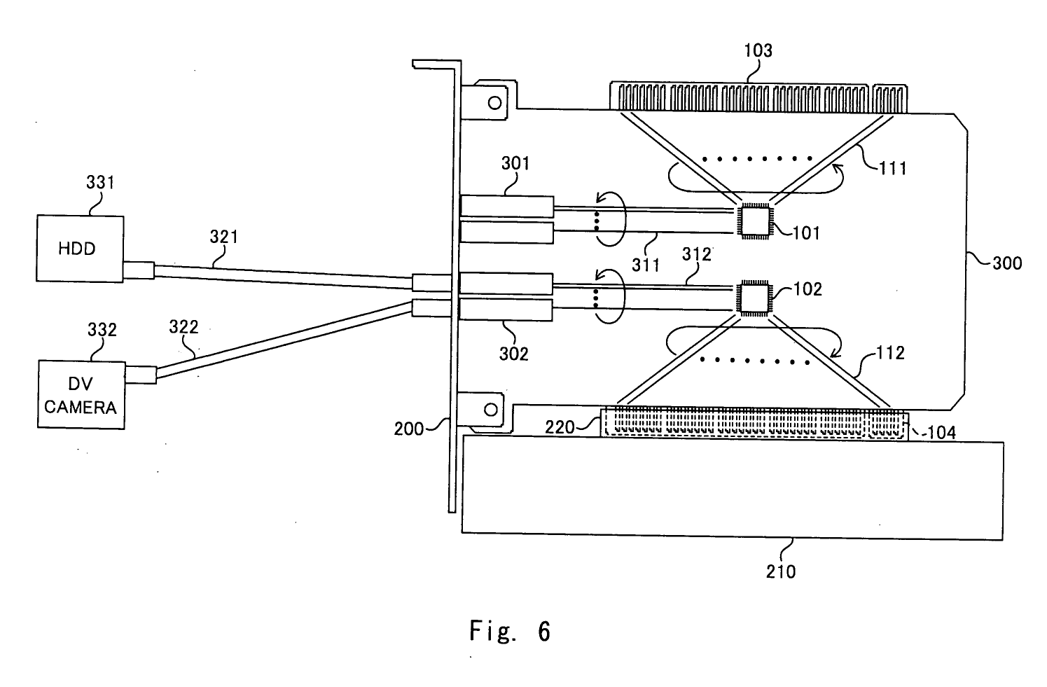

A mode of use of the adapter card 300 according to the second embodiment is described hereinafter in detail with reference to FIG. 6. FIG. 6 is a plan pattern view showing a mode of use of the adapter card 300 according to the second embodiment. Note that the connection configuration of the adapter card 300 and bracket 200 is same as the first embodiment, thus the explanation will not be repeated here. Moreover, the adapter card 300 is turned upside down according to the function to select so as to be mounted to the computer 210.

The function to use is selected by a user request for the adapter card 300 of the second embodiment. Specifically as shown in FIG. 6, when a user uses cables for IEEE 1394 321 and 322, the second male connector 104 is inserted into the female connector 220 of the computer 210. This enables the computer 210 to exchange signals with the second LSI 102, and the user is able to use the function of the second LSI 102.

One end of the cable for IEEE 1394 321 is connected to a hard disk drive (HDD) 331 and another end is connected to the device side connector 302. Further, one end of the cable for IEEE 1394 is connected to a digital video (DV) camera 332 and another end is inserted into the device side connector 302. As the second LSI 102 is connected to the device side connector 302 via the wiring group 312, data exchange with the hard disk 331 and digital camera 332 can be performed. In this way, the computer 210 is able to exchange data between the hard disk 331 and digital camera 332 via the second LSI 102.

When the user uses a cable for USB, the adapter card 300 is turned upside down to re-fix to the bracket 200. The male connector 103 is inserted into the male connector 220 of the computer 210 in this state. This enables the computer 210 to exchange signals with the first LSI 101, thus the user is able to use the function of the first LSI 101.

A peripheral device is connected to the connector 301 by a cable for USB. As the first LSI 101 is connected to the device side connector 301 via the wiring group 311, the first LSI 101 can exchange data with the peripheral device. This enables the computer 210 to exchange data with the peripheral device via the first LSI 101.

As described in the foregoing, in addition to the advantageous effects by the first embodiment, the second embodiment is able to cover the case in which a peripheral device connecting to the adapter card 300 only includes either of the interface of USB or IEEE 1394. Specifically, by changing the direction to insert the adapter card 300 into the computer 210, data exchange can be performed between the peripheral device and computer 210 in either case of the USB or IEEE 1394.

### Third Embodiment

In a third embodiment, an adapter card is described in which two LSIs perform particular functions as with the second embodiment but the LSIs perform the same function having different characteristics. Specifically, in the adapter card of the third embodiment, the LSIs 101 and 102 respectively function as a first data link layer controller and a second data link layer controller in the IEEE 1394.

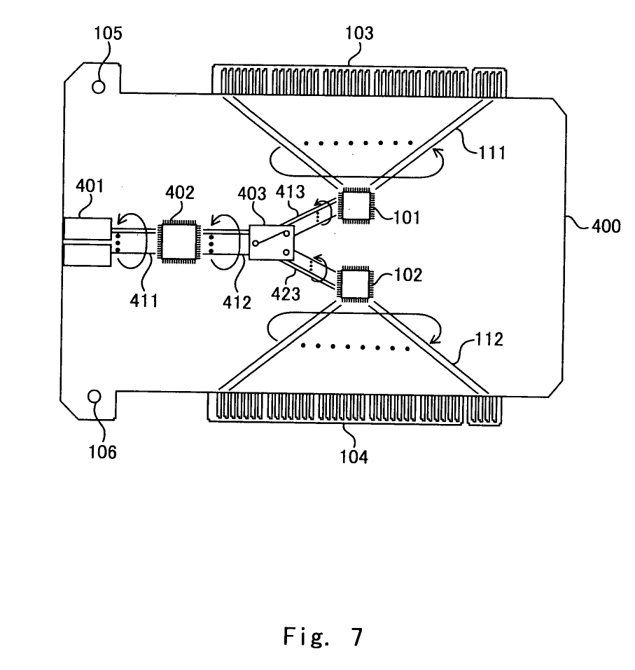

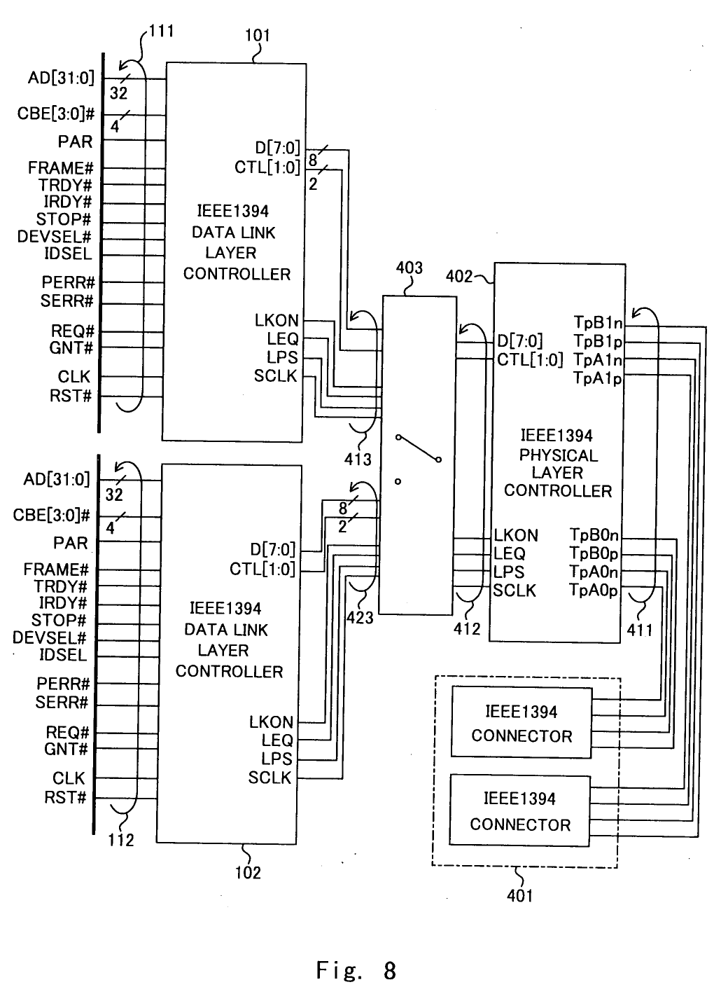

The configuration of the adapter card according to the third embodiment is described hereinafter in detail with reference to FIGS. 7 and 8. FIG. 7 is a plan pattern view showing a structure example of an adapter card according to the third embodiment. In the description that follows, like parts as the adapter card 300 of the second embodiment are marked throughout the specification with the same reference numerals with their description omitted. As shown in FIG. 7, the adapter card 400 includes a device side connector 401, third LSI 402 and bus switching circuit 403 in addition to the configuration of the second embodiment.

The device side connector 401 is placed over the principle surface of the rectangle card 400 and is fixed to the surface where the LSIs 101 and 102 are placed. Specifically, the device side connector 401 is placed near the short side where the screw holes 105 and 106 are provided. The device side connector 401 is connected to a wiring group 411 and to a terminal for IEEE 1384 of a third LSI 402 via the wiring group 411.

The third LSI 402 is an example of a circuit device for performing a particular function that is different from the LSIs 101 and 102 and functions as a physical layer controller for IEEE 1394. The third LSI 402 is connected to a wiring group 412 and to a bus switching circuit 403 via the wiring group 412. Furthermore, the wiring group 411 may connect the device side connector 401 with the third LSI 402 and the wiring group may connect the third LSI 402 with the bus the bus switching circuit 403, however in FIG. 7, they extend along the direction of a long side of the adapter card 400.

The bus switching circuit 403 switches buses that connect each of the LSIs 101 and 102 and third LSI 402. The bus switching circuit 403 is connected to each of wiring group 413 and 423 and to each of terminals for physical layer of the LSIs 101 and 102 via the wiring groups 413 and 423. The wiring group 413 may connect the bus switching circuit 403 with LSI 101 and the wiring group 423 may connect the bus switching circuit 403 with LSI 102 independently from each other. In FIG. 7, the wiring groups 413 and 423 are formed inclined toward the direction of the long side of the adapter card 400.

A wiring structure of the adapter card 400 according to the third embodiment is described hereinafter in detail with reference to FIG. 8.

FIG. 8 is a block diagram showing an example of a wiring structure of the adapter card 400 according to the third embodiment. As shown in FIG. 8, the wiring groups 111 and 413 and wiring groups 112 and 423 that are connected to the LSIs 101 and 102 are completely independent. The LSI 101 and 102 are connected to the male connectors 103 and 104 via the wiring groups 111 and 112 respectively. The bus switching circuit 403 can be used to select for connecting the third LSI 402 with either of the LSI 101 or 102.

Specifically, the first LSI 101 that functions as a data link layer controller for the first IEEE 1394 inputs/outputs various signals “AD[31:0]”, “CBE[3:0]”, . . . with the computer 210 via the wiring group 111. The first LSI 101 inputs/outputs various signals “D[7:0]”, “CTL[1:0]”, . . . with the bus switching circuit 402 via the wiring group 413.

The bus switching circuit 403 inputs/outputs various signals “D[7:0]”, “CTL[1:0]”, . . . with the third LSI 402 that functions as a physical layer controller for IEEE 1394 via the wiring group 412. The third LSI 402 inputs/outputs “TpB1n”, “TpB1p”, . . . with the IEEE 1394 connector 401 via the wiring 411. This enables the computer 210 to input/output various signals with a peripheral device having an IEEE 1394 interface with a first characteristic.

The second LSI 102 that functions as a data link layer controller for the second IEEE 1394 inputs/outputs various signals “AD[31:0]”, “CBE[3:0]”, . . . with the computer 210 via the wiring group 112. The second LSI 102 inputs/outputs various signals “D[7:0]”, “CTL[1:0]”, . . . with the bus switching circuit 403 via the wiring group 312.

The bus switching circuit 403 inputs/outputs various signals “D[7:0]”, “CTL[1:0]”, . . . with the third LSI 402 that functions as a physical layer controller for IEEE 1394 via the wiring group 412. The third LSI 402 inputs/outputs various signals “TpB1n”, “TpB1p”, . . . with the IEEE 1394 connector 401 via the wiring 411. This enables the computer 210 to input/output various signals with a peripheral device having an IEEE 1394 interface with a second characteristic.

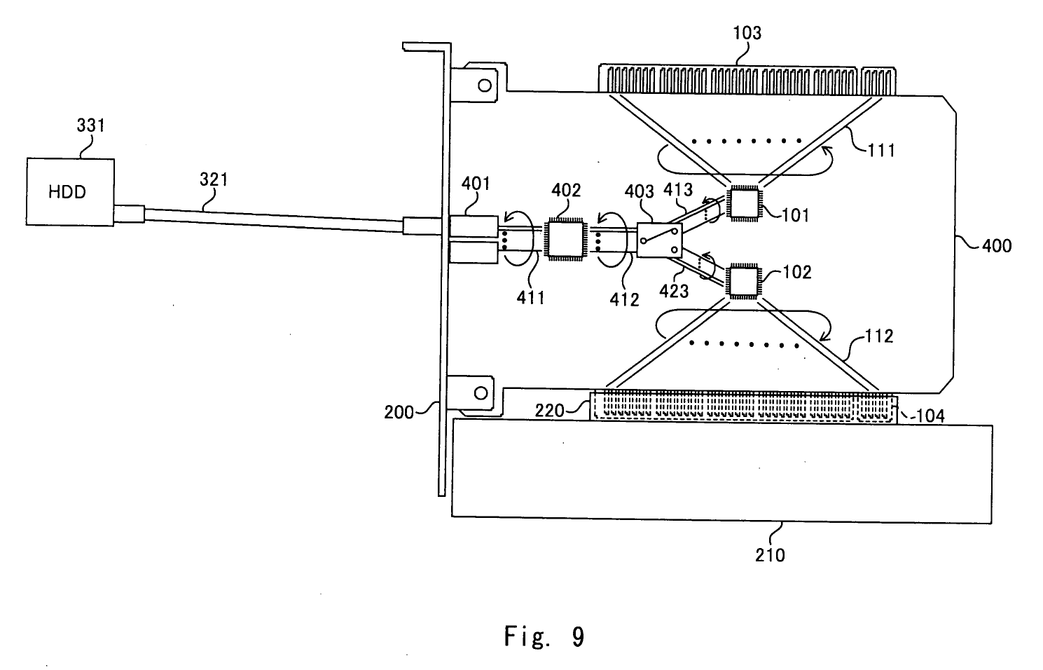

A mode of use of the adapter card 400 according to the third embodiment is described hereinafter in detail with reference to FIG. 9. FIG. 9 is a plan pattern view showing a mode of use of the adapter card 400 according to the third embodiment. Note that the connection configuration of the adapter 300 according to the third embodiment is same as the first embodiment, thus the explanation will not be repeated here. Further, the adapter card 400 is turned upside down according to the characteristics to use and mounted to the computer 210. This is also same as the first embodiment, thus the explanation will not be repeated here.

The adapter card 400 of the third embodiment can be used to evaluate whether the third LSI 402 is properly operating by connecting either of the LSI 101 or 102 in the same environment. Specifically, the characteristic of the semiconductor may differ due to the manufacturing fluctuation of LSIs caused by different production lot or different manufacturer. In such case, even if the functions of the LSIs 101 and 102 are the same, connectivity of the third LSI 402 that functions as a physical layer controller and the LSIs 101 and 102 can be checked using only one adapter card 400.

As shown in FIG. 9, if a tester checks the connectivity between the third LSI 402 and second LSI 102, the second male connector 104 is inserted into the female connector 220 of the computer 210. This enables the computer 210 to exchange signals with the second LSI 102, thus the functions of the second LSI 102 can be used.

In response to the insertion of the second male connector 104, the second LSI 102 inputs a switch control signal to the bus switching circuit 403 via the wiring group 423. The second LSI 102 and the bus switching circuit 403 select the second LSI 102. The second LSI 102 switches the bus switching circuit 403 to the side of the wiring group 423 and the bus switching circuit 403 selects the second LSI 102. The second LSI 102 is able to exchange data with the third LSI 402 via the wiring group 412.

One end of the cable for IEEE 1394 is connected to the hard disk 331 and another end is inserted into the device side connector 401. As the third LSI 402 is connected to the device side connector 401 via the wiring group 411, data exchange between the hard disk 331 can be performed. This enables the second LSI 102 to exchange data with the hard disk 331 via the third LSI 402 and also the computer 210 to exchange data with the hard disk 331.

When a tester checks the connectivity between the third LSI 402 and first LSI 101, it can be done as with the case of checking the connection between the second LSI 102. Specifically, the first male connector 103 of the adapter card 400 is inserted into the female connector 220 of the computer 210. This enables to use the function of the first LSI 101 and also the first LSI 101 to exchange data with the hard disk 331 via the third LSI 402.

In this way, the tester uses the adapter card 400 of the third embodiment to check connectivity with each of the LSIs 101 and 102 having different characteristics from the third LSI 402 to compare between them. Therefore, difference between the operations of the LSIs 101 and 102 can be evaluated economically using only one adapter card. Further, the wiring groups 412, 111 and 413, and wiring groups 412, 112 and 412 concerning the LSIs 101 and 102 are independent to each other. Thus the functions of the LSIs 101 and 102 can be evaluated in a condition close to an actual operation.

It is apparent that the present invention is not limited to the above embodiments, but may be modified and changed without departing from the scope and spirit of the invention.

What is claimed is:

1. A circuit board comprising:
a main board; and
a plurality of connectors selectively inserted and removed into/from a same slot.

2. The circuit board according to claim 1, wherein each of the plurality of connectors includes a plurality of metal terminals electrically connected with the slot, and
the plurality of metal terminals provided to each of the plurality of connectors has same arrangement.

3. The circuit board according to claim 1, wherein the plurality of connectors are placed symmetric with respect to a center line perpendicular to a direction inserted and removed into/from the slot.

4. The circuit board according to claim 3, wherein the plurality of connectors are placed symmetric with respect to a pair of opposite sides, the opposite sides being parallel to the center line.

5. The circuit board according to claim 1, further comprising a device side connector provided separately from the plurality of connectors and also connected to an external device.

6. The circuit board according to claim 4, further comprising a device side connector provided separately from the plurality of connectors and also connected to an external device.

7. The circuit board according to claim 6, wherein the device side connector is placed to a side different from the pair of opposite sides.

8. The circuit board according to claim 3, wherein
the circuit board is fixed to a bracket, and
among the plurality of connectors, from a state another connector different from a predetermined connector is mounted to the bracket, the predetermined connector is rotated 180 degrees around the center line and mounted to the bracket.

9. The circuit board according to claim 8, further comprising a plurality of fixing parts to fix to the bracket,
wherein the plurality of fixing parts are placed symmetric with respect to the center line.

10. The circuit board according to claim 1, further comprising:
a plurality of circuit devices electrically connected with each of the plurality of connectors; and
a plurality of wiring groups to connect the plurality of circuit devices with each of the plurality of connectors.

11. The circuit board according to claim 10, further comprising:
a predetermined circuit device electrically and independently connected to each of the plurality of circuit devices; and
a switching circuit to switch a connection of the predetermined circuit device with each of the plurality of circuit devices.

12. The circuit board according to claim 1, wherein the switching circuit selects a circuit device connected to a connector mounted to the slot from the plurality of circuit device according to the connector mounted to the slot.

13. The circuit board according to claim 11, wherein the predetermined circuit device is a physical layer controller electrically connected to the device side connector, and
the plurality of circuit devices are upper layer controller for the physical layer controller.

14. The circuit board according to claim 1, wherein the plurality of connectors are compliant to PCI bus standard, ISA bus standard or PCI-Express standard.

15. The circuit board according to claim 5, wherein the device side connector is compliant to standards including USB standard and IEEE 1394 standard.
